(19) United States
(12) Patent Application Publication
(10) Pub. No.: US 2016/0097236 A1
(43) Pub. Date: Apr. 7, 2016

(54) PHOTOREACTIVE SMART WINDOW

(71) Applicant: KOREA INSTITUTE OF SCIENCE AND TECHNOLOGY, Seoul (KR)

(72) Inventors: Doo-Hyun KO, Seoul (KR); Byoung-Kwon MIN, Seoul (KR); Hyun-Keun KWON, Seoul (KR); Kyu-Tae LEE, Seoul (KR); Hyungduk KO, Seoul (KR); Ilki HAN, Seoul (KR)

(21) Appl. No.: 14/842,029

(22) Filed: Sep. 1, 2015

(30) Foreign Application Priority Data
Oct. 1, 2014 (KR) 10-2014-0132490

(51) Int. Cl. E06B 9/24; H01L 31/054; G02F 1/00; G02F 1/13; G02F 1/1335

(52) U.S. Cl. CPC E06B 9/24; G02F 1/1313; G02F 1/133528; G02F 1/0045; H01L 31/054; E06B 2009/2464; E06B 2009/2476

(57) ABSTRACT

Provided is a photoreactive smart window. The photoreactive smart window includes a liquid crystal layer of which light transmittance changes according to the presence of ultraviolet (UV) light and which is combined with a solar cell. The photoreactive smart window is in a transparent condition in the daytime when UV light is generated from the sun, and accordingly sunlight passing therethrough is converted into electric energy. Also, the photoreactive smart window is in an opaque condition in the evening and at night when no UV light is generated from the sun, and accordingly no curtains are necessary on the windows.

### RELATED APPLICATION

This application claims the benefit of Korean Patent Application No. 10-2014-0132490, filed on Oct. 1, 2014, in the Korean Intellectual Property Office, the disclosure of which is incorporated herein in its entirety by reference.

### BACKGROUND

1. Field

One or more exemplary embodiments relate to a photosensitive smart window, and more particularly, to a photosensitive smart window that is capable of adjusting light transmittance according to the presence or absence of ultraviolet (UV) light without any use of external energy and that is combined with a solar cell to form a new type of an electricity-generation smart window.

2. Description of the Related Art

A solar cell capable of directly generating electricity using sunlight is considered as the most promising future energy production method in terms of generating clean energy in a safe manner.

A solar cell can be developed by using Building Integrated Photovoltaics (BIPV) technology. Particularly, in recent years, solar cells are being applied to green building technologies and policies in correspondence with environmental regulations at home and abroad. For example, such technologies and policies are associated with EU RoHS REACH, Halogen Free, and WEEE in Europe, California RoHS in the U.S.A., China RoHS in China, and J-Moss in Japan regarding a zero-energy architecture and a regulation on carbon emissions, and with the laws on resource circulation of electric/electronic products and automobiles in Korea. In addition, solar cells may be used to generate new and renewable energies, and will be applied for buildings and industrial facilities in an increasing manner.

Meanwhile, a smart window with adjustable optical permeability has been studied extensively in consideration of a window without the need of curtains. In some cases, a smart window is applied to architectures, car windows, car sunroofs, or the like. Technologies for manufacturing such a switchable window are broadly classified according to materials, e.g., electrochromic materials, liquid crystal, and electrophoresis/suspended particles, and each of the technologies has unique characteristics and advantages. A typical smart window is manufactured based on an electrochromic system, which requires external energy to switch between a transparent state and an opaque state.

As such, the light transmittance of an existing smart window is adjusted according to external power independently applied thereto. The smart window is used for adjusting the light transmittance of a solar cell.

### SUMMARY

One or more exemplary embodiments include a photoreactive smart window that is capable of adjusting light transmittance according to the presence or absence of ultraviolet (UV) light without any use of external energy and that is combined with a solar cell to generate electricity.

Additional aspects will be set forth in part in the description which follows and, in part, will be apparent from the description, or may be learned by practice of the presented embodiments.

According to one or more exemplary embodiments, a photoreactive smart window includes:
an upper polarizer and a lower polarizer that are arranged at a separation distance from each other;
a liquid crystal layer between the upper polarizer and the lower polarizer and including an achiral nematic liquid crystal, a photoreactive azobenzene compound, and a chiral dopant; and
a solar cell.

The solar cell may be disposed on a top surface of the upper polarizing plate, on a bottom surface of the lower polarizing plate, between the upper polarizer and the liquid crystal layer, or between the lower polarizer and the liquid crystal layer.

### BRIEF DESCRIPTION OF THE DRAWINGS

These and/or other aspects will become apparent and more readily appreciated from the following description of the embodiments, taken in conjunction with the accompanying drawings in which:

FIG. 1 shows diagrams describing the principles of light transmission and light interception in a liquid crystal layer used in a photoreactive smart window according to an exemplary embodiment;

FIGS. 2A and 2B respectively show diagrams illustrating energy of azobenzene compounds of Formulae 3 and 4 used in an exemplary embodiment under conditions associated with a trans-conformation, a cis-conformation, and an intermediate transition state;

FIG. 3 is a vertical cross-sectional diagram illustrating a photoreactive smart window according to an exemplary embodiment;

FIG. 4 is a vertical cross-sectional diagram illustrating a photoreactive smart window according to another exemplary embodiment;

FIG. 5 is a vertical cross-sectional diagram illustrating a photoreactive smart window according to another exemplary embodiment;

FIG. 6 is a vertical cross-sectional diagram illustrating an example of a dye-sensitized solar cell that may be used in a photoreactive smart window according to an exemplary embodiment;

FIGS. 7A and 7B respectively show images of a liquid crystal layer in a state before exposure to ultraviolet (UV) light and in a state after exposure to UV light, respectively, wherein the liquid crystal layer is prepared according to Example 1 and is inserted between polarizers that intersect each other;

FIGS. 8A and 8B respectively show images of a photoreactive smart window in a state before exposure to UV light and in a state after exposure to UV light, respectively, wherein the photoreactive smart window is prepared according to Example 1 and includes a liquid crystal layer combined with a dye-sensitized solar cell (DSSC);

FIG. 9 is a graph for comparing light transmittance of a liquid crystal layer with absorption wavelength of a dye used in a photoreactive smart window, wherein the liquid crystal layer is prepared according to Example 1 and is inserted between polarizers that intersect each other; and

FIG. 10 is a graph for evaluating switching performance between a ‘night mode’ and a ‘day mode’ of a photoreactive smart window prepared according to Example 1.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the exemplary embodiments are merely described below, by referring to the figures, to explain aspects of the present description. Expressions such as “at least one of,” when preceding a list of elements, modify the entire list of elements and do not modify the individual elements of the list.

According to an aspect of the inventive concept, a photoreactive smart window includes:

an upper polarizer and a lower polarizer that are arranged at a separation distance from each other;

a liquid crystal layer between the upper polarizer and the lower polarizer and including an azobenzene compound, an achiral nematic liquid crystal, and a chiral dopant; and

a solar cell on a top surface of the upper polarizer, on a bottom surface of the lower polarizer, between the upper polarizer and the liquid crystal layer, or between the lower polarizer and the liquid crystal layer.

In the photoreactive smart window, the liquid crystal layer capable of adjusting light transmittance according to the presence or absence of ultraviolet (UV) light may be combined with a solar cell, so as to automatically switch between a transparent state and an opaque state in accordance with surrounding environment and light conditions. The photoreactive smart window uses a light-convertible liquid crystal layer. Thus, if the photoreactive smart window is in a transparent state in the presence of UV light during the daytime, sunlight passing through the photoreactive smart window may be converted into electric energy via the solar cell. Alternatively, if the photoreactive smart window is in an opaque state in the absence of UV light at night, the photoreactive smart window may be used as a window without the need of curtains.

The upper polarizer and the lower polarizer may intersect each other at a right angle, and the liquid crystal layer may be inserted between the two polarizers.

The liquid crystal layer may be formed of light-convertible liquid crystal, and may include an achiral nematic liquid crystal, a photoreactive azobenzene compound, and a chiral dopant.

The achiral nematic liquid crystal may have a helical structure with a helical axis along a thickness direction of the liquid crystal layer, and a pitch of the helical structure may be adjusted by the photoreactive azobenzene compound according to the presence or absence of UV light.

The photoreactive azobenzene compound may be subjected to cis-trans isomerization in response to external light, such as UV light. The photoreactive azobenzene compound has a structure of a trans isomer in the absence of UV light, and has a structure of a cis isomer in the presence of UV light.

The photoreactive azobenzene compound having the trans isomeric structure shortens the pitch of the helical structure of the achiral nematic liquid crystal, and thus external light passing through the upper polarizer may be intercepted. That is, the photoreactive smart window is in a dark state in the absence of UV light. Here, the dark state is referred to as a “night mode”.

The photoreactive azobenzene compound having the cis isomeric structure lengthens the pitch of the helical structure of the achiral nematic liquid crystal, and thus external light passing through the upper polarizer may also pass through the liquid crystal layer. That is, the photoreactive smart window is in a transparent state in the presence of UV light is. Here, the transparent state is referred to as a “day mode”.

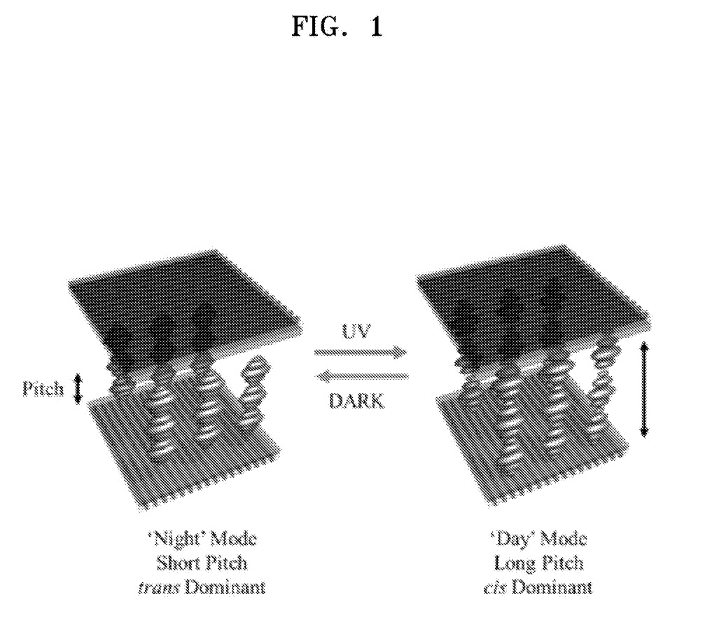

FIG. 1 shows diagrams describing the principles of light transmission and light interception in the liquid crystal layer.

Referring to FIG. 1, the azobenzene compound has a trans isomeric structure in the absence of UV light, so that the liquid crystal having a shortened pitch intercepts light passing through the upper polarizer, thereby providing a “night mode”. Alternatively, the azobenzene compound has a cis isomeric structure in the presence of UV light, so that the liquid crystal having a lengthened pitch allows external light to pass therethrough, thereby providing a “day mode”. According to exposure to UV light, the switch between the night mode and the day mode may be repeated.

FIG. 8 shows images of the photoreactive smart window prepared by stacking the liquid crystal layer and a transparent solar cell, according to Examples below. The photoreactive smart window shown in FIG. 8A is in a state where light is intercepted. When the photoreactive smart window of FIG. 8A is exposed to external light, it is confirmed that the structure of the photoreactive smart window of FIG. 8A is changed to a structure that allows light to pass through the photoreactive smart window as shown in FIG. 8B.

Any compound that has an azobenzene skeletal structure may be used without limitation as the azobenzene compound configured to have light conversion capability.

In an exemplary embodiment, the azobenzene compound may include a compound represented by Formula 1 below:

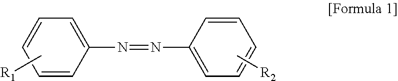

In Formula 1, R₁ and R₂ may be each independently a hydrogen, a substituted or unsubstituted C₁-C₃₀ alkyl group, a substituted or unsubstituted C₁-C₃₀ alkoxy group, a substituted or unsubstituted C₆-C₃₀ aryl group, a substituted or unsubstituted C₆-C₃₀ aryloxy group, a substituted or unsubstituted C₃-C₃₀ heteroaryl group, a substituted or unsubstituted C₃-C₃₀ heteroaryloxy group, a substituted or unsubstituted C₄-C₃₀ cycloalkyl group, or a substituted or unsubstituted C₃-C₃₀ heterocycloalkyl group,

wherein the aryl group, the aryloxy group, the heteroaryl group, and the heteroaryloxy group may be hybridized to at least two carbon atoms of a combined benzene ring.

In another exemplary embodiment, the azobenzene compound may include a compound represented by Formula 2 below:

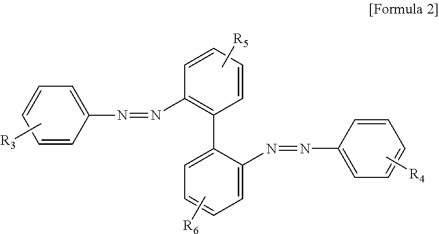

In Formula 2, R₃ and R₆ may be each independently a hydrogen, a substituted or unsubstituted C₁-C₃₀ alkyl group, a substituted or unsubstituted C₁-C₃₀ alkoxy group, a substituted or unsubstituted C₆-C₃₀ aryl group, a substituted or unsubstituted C₆-C₃₀ aryloxy group, a substituted or unsubstituted C₃-C₃₀ heteroaryl group, a substituted or unsubstituted C₃-C₃₀ heteroaryloxy group, a substituted or unsubstituted C₄-C₃₀ cycloalkyl group, or a substituted or unsubstituted C₃-C₃₀ heterocycloalkyl group,

wherein the aryl group, the aryloxy group, the heteroaryl group, and the heteroaryloxy group may be hybridized to at least two carbon atoms of a combined benzene ring.

Substituents used in formulae above may be defined as follows.

The term “alkyl” used herein refers to a fully saturated, branched or non-branched (e.g., straight or linear), hydrocarbon.

Non-limiting examples of the “alkyl” are methyl, ethyl, n-propyl, isopropyl, n-butyl, isobutyl, sec-butyl, n-pentyl, isopentyl, neopentyl, iso-amyl, n-hexyl, 3-methylhexyl, 2,2-dimethylpentyl, 2,3-dimethylpentyl, and n-heptyl.

At least one hydrogen of the alkyl” may be substituted with a halogen, a C₁-C₂₀ alkyl group which is substituted with a halogen (e.g., CCF₃, CHCF₂, CH₂F, and CCl₃), a C₁-C₂₀ alkoxy group, a C₂-C₂₀ alkoxyalkyl group, a hydroxyl group, a nitro group, a cyano group, an amino group, an amidino group, a hydrazine, a hydrazone, a carboxyl group or a salt thereof, a sulfonyl group, a sulfamoyl group, a sulfonic acid or a salt thereof, a C₁-C₂₀ alkyl group, a C₂-C₂₀ alkenyl group, a C₂-C₂₀ alkynyl group, a C₁-C₂₀ heteroalkyl group, a C₆-C₂₀ aryl group, a C₆-C₂₀ arylalkyl group, a C₆-C₂₀ heteroaryl group, a C₇-C₂₀ heteroarylalkyl group, a C₆-C₂₀ heteroaryloxy group, a C₆-C₂₀ heteroaryloxyalkyl group, or a C₆-C₂₀ heteroaryl alkyl group.

The term “halogen” used herein refers to fluorine, bromine, chlorine, or iodine.

The term “C₁-C₂₀ alkyl group substituted with a halogen” used herein refers to a C₁-C₂₀ alkyl group substituted with at least one halo group, and non-limiting examples thereof are monohaloalky, dihaloalkyl, and polyhaloalkyl including perhaloalkyl.

The monohaloalkyl used herein refers to an alkyl group containing one selected from iodine, bromine, chlorine, and fluorine, and the dihaloalkyl and the polyhaloalkyl used herein refer to an alkyl group containing at least two halogens that are identical to or different from each other.

The term “alkoxy” used herein refers to a formula represented by alkyl-O—, wherein the alkyl is defined the same as above. Non-limiting examples of the alkoxy are methoxy, ethoxy, propoxy, 2-propoxy, butoxy, tert-butoxy, pentyloxy, hexyloxy, cyclopropoxy, and cyclohexyloxy. At least one hydrogen of the alkoxy group may be substituted with the same substituent used in the alkyl group above.

The term “alkoxyalkyl” used herein refers to an alkyl group substituted with the alkoxy described above. At least one hydrogen of the alkoxyalkyl group may be substituted with the same substituent used in the alkyl group above. As such, the term “alkoxyalkyl” includes a substituted alkoxyalkyl moiety.

The term “alkenyl” used herein refers to a branched or non-branched hydrocarbon having at least one carbon-carbon double bond. Non-limiting examples thereof are vinyl, aryl, butenyl, iso-prophenyl, and iso-butenyl. At least one hydrogen of the alkenyl group may be substituted with the same substituent used in the alkyl group above.

The term alkynyl” used herein refers to a branched or non-branched hydrocarbon having at least one carbon-carbon triple bond. Non-limiting examples thereof are ethinyl, butinyl, iso-butinyl, and isopropynyl.

At least one hydrogen of the alkynyl group may be substituted with the same substituent used in the alkyl group above.

The term “aryl group” used herein refers to an aromatic hydrocarbon group that is used alone or in combination and includes at least one ring.

The term “aryl group” used herein also refers to a group in which an aromatic ring is fused to at least one cycloalkyl ring.

Non-limiting examples of the aryl are a phenyl group, a naphthyl group, and a tetrahydronaphthyl group.

In addition, at least one hydrogen of the aryl group may be substituted with the same substituent used in the alkyl group above.

The term “arylalkyl” used herein refers to an alkyl group substituted with an aryl. An example of the arylalkyl group is benzyl-CH₂CH₂— or phenyl-CH₂CH₂—.

The term “aryloxy” used herein refers to —O-aryl, and an example of the aryloxy is phenoxy. At least one hydrogen of the aryloxy group may be substituted with the same substituent used in the alkyl group.

The term “heteroaryl” group used herein refers to a monocyclic or bicyclic organic compound including at least one heteroatom selected from nitrogen (N), oxygen (O), phosphorus (P), and sulfur (S), and carbons as remaining ring-forming atoms. The heteroaryl group may include, for example, 1 to 5 heteroatoms and 5 to 10 ring members. Here, S or N may be oxidized, so as to have a number of different oxidation states.

At least one hydrogen of the aryloxy group may be substituted with the same substituent used in the alkyl group.

The term “heteroarylalkyl” used herein refers to alkyl substituted with heteroaryl.

The term “heteroaryloxy” used herein refers to a —O-heteroaryl moiety. At least one hydrogen of the heteroaryloxy group may be substituted with the same substituent used in the alkyl group.

The term “heteroaryloxyalkyl” used herein refers to an alkyl substituted with —O-heteroaryl. At least one hydrogen of the heteroaryloxyalkyl group may be substituted with the same substituent used in the alkyl group.

The term “carbon ring” used herein refers to a saturated non-aromatic monocyclic, bicyclic, or tricyclic hydrocarbon or a partially unsaturated non-aromatic monocyclic, bicyclic, or tricyclic hydrocarbon.

Examples of the monocyclic hydrocarbon are cyclopentyl, cyclopentenyl, cyclohexyl, cyclohexenyl, and the like, and examples of the bicyclic hydrocarbon are bornyl, decahydronaphthyl, bicyclo[2.1.1]hexyl, bicyclo[2.2.1]heptyl, bicyclo[2.2.1]heptenyl, bicyclo[2.2.2]octyl, and the like.

An example of the tricyclic hydrocarbon is adamantly.

At least one hydrogen of the carbon ring may be substituted with the same substituent used in the alkyl group.

The term “heterocyclic” group used herein refers to a 5-10 membered heterocyclic group containing a heteroatom such as N, G, P, and O. An example thereof is pyridyl. Here, at least one hydrogen of the heterocyclic group may be substituted with the same substituent used in the alkyl group.

The term “heterocyclic oxy” used herein refers to a —O-heterocycle. Here, at least one hydrogen of the heterocyclic oxy group may be substituted with the same substituent used in the alkyl group.

The term “sulfonyl” used herein refers to R″—SO₂—, wherein R″ is a hydrogen, alkyl, aryl, heteroaryl, aryl-alkyl, heteroaryl-alkyl, alkoxy, aryloxy, a cycloalkyl group, or a heterocyclic group.

The term “sulfamoyl” used herein refers to H₂NS(O₂)—, alkyl-NHS(O₂)—, (alkyl)₂NS(O₂)-aryl-NHS(O₂)—, alkyl-(aryl)-NS(O₂)—, (aryl)₂NS(O)₂, heteroaryl-NHS(O₂)—, (aryl-alkyl)-NHS(O₂)—, or (heteroaryl-alkyl)-NHS(O₂)—.

At least one hydrogen of the sulfamoyl group may be substituted with the same substituent used in the alkyl group.

The term “amino group” used herein refers to a group of which N is covalently bonded to at least one carbon or heteroatom. Examples of the amino group are —NH₂, a substituted moiety, and the like. In addition, the amino group includes an alkylamino group of which N is additionally bonded to at least one alkyl group, and “an arylamino group” and “a diarylamino group” of which N is bonded to at least one or two aryl groups that are independently selected.

In an exemplary embodiment, the azobenzene compound may include a compound represented by Formula 3 below and/or a compound represented by 4 below. For example, the compound of Formula 3 may be used alone or in a combination with the compound of Formula 4.

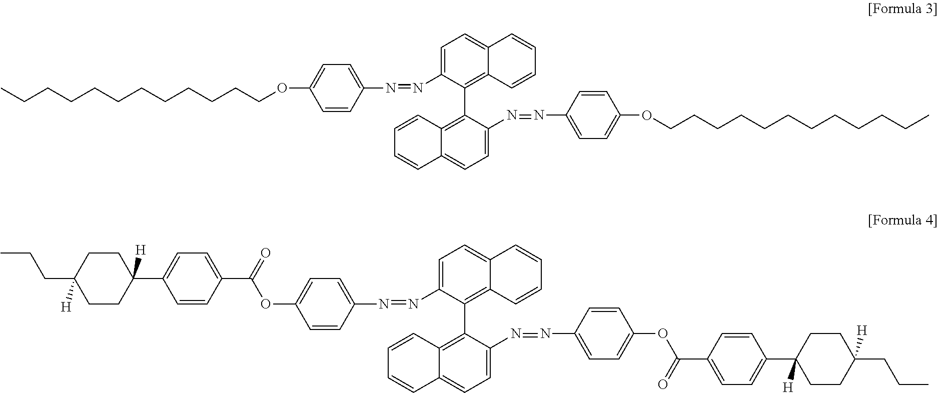

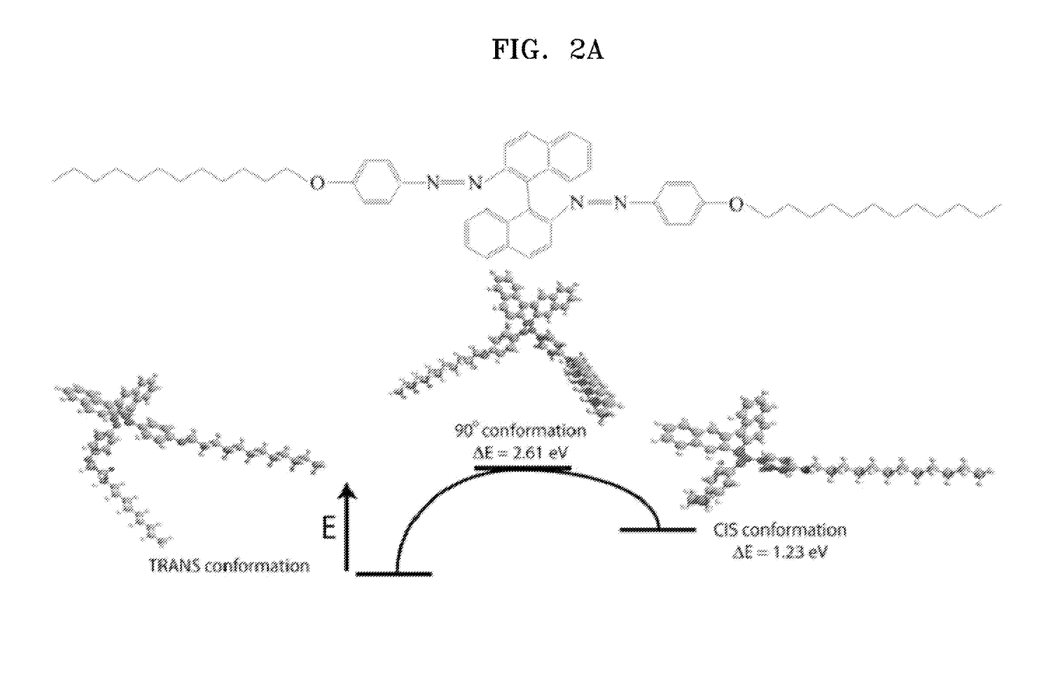

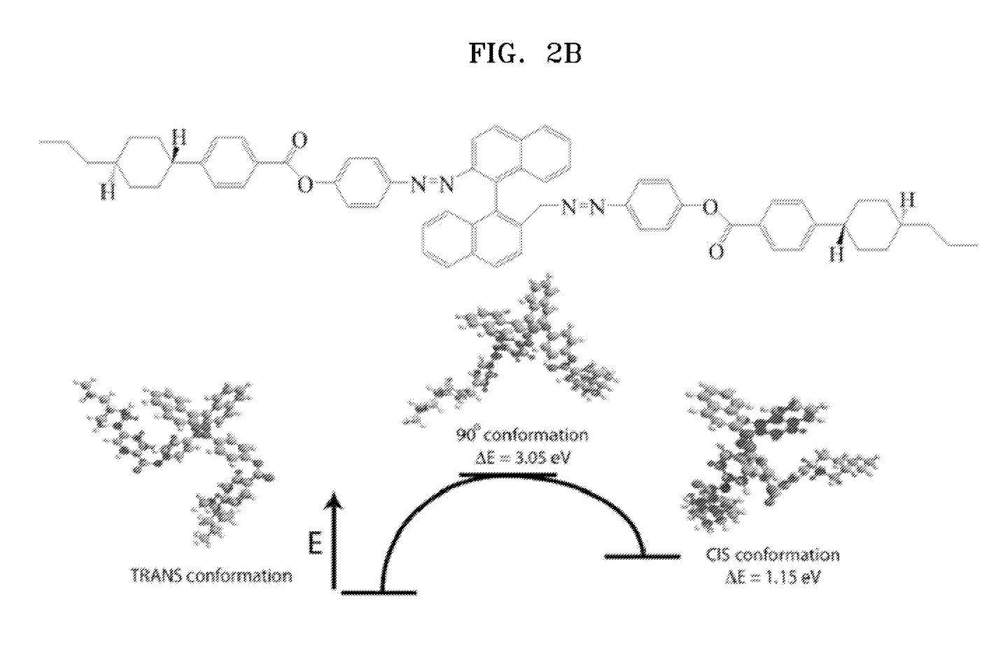

FIGS. 2A and 2B respectively show diagrams illustrating energy of azobenzene compounds of Formulae 3 and 4 used in an exemplary embodiment under conditions associated with a trans-conformation, a cis-conformation, and an intermediate transition state. Referring to FIGS. 2A and 2B, energy in an intermediate transition state between trans conformation and 90° conformation of the compound of Formula 3 is relatively lower than that of the compound of Formula 4. Thus, trans-cis isomerization is more likely to occur in the compound of Formula 3 in response to external power (i.e., UV exposure).

However, since the compound of Formula 4 has a higher energy barrier than that of compound of Formula 3, and thus the compound of Formula 4 may maintain its trans conformation regardless of expose to UV. Therefore, the compound of Formula 4 and the compound of Formula 3 are added together, so as to improve restoration ability of the achiral nematic liquid crystal to its initial state, i.e., a dark state, in the absence of UV light.

Here, the compound of Formula 3 and the compound of Formula 4 may be used in a ratio that is adjusted according to a wavelength area of light blocked out. For example, the compound of Formula 3 and the compound of Formula 4 may be used in a molar ratio in a range of about 1:100 to about 100:1. In particularly, the compound of Formula 3 and the compound of Formula 4 may be used in a molar ratio in a range of about 1:50 to about 50:1, about 1:10 to about 10:1, or about 1:2 to about 2:1. In particularly, the compound of Formula 3 and the compound of Formula 4 may be used in a molar ratio, for example, 1:1. When the compound of Formula 3 and the compound of Formula 4 may be used in a molar ratio within the ranges above, the initial state of the achiral nematic liquid crystal, i.e., a dark state, may be stably restored in the absence of UV.

Meanwhile, the chiral dopant is a photo-insensitive material, and is used to induce a sufficiently short pitch from a helical structure of the achiral nematic liquid crystal. Any material may be used as the chiral dopant, so long as the material induces the helical structure of the achiral nematic liquid crystal without damaging the nematic regularity.

As such, the liquid crystal layer may include the achiral nematic liquid crystal, the photoreactive azobenzene compound, and the chiral dopant, and accordingly, may switch the condition of the photoreactive smart window between a transparent state and an opaque state according to the presence or absence of UV light without requiring external power. In addition, the photoreactive smart window combined with a solar cell is in an opaque state in daytime, thereby generating electricity, and is in a dark state in nighttime, thereby acting as a shutter for privacy, and that is, the photoreactive smart window in a dark state may be used as a window without the need of curtains.

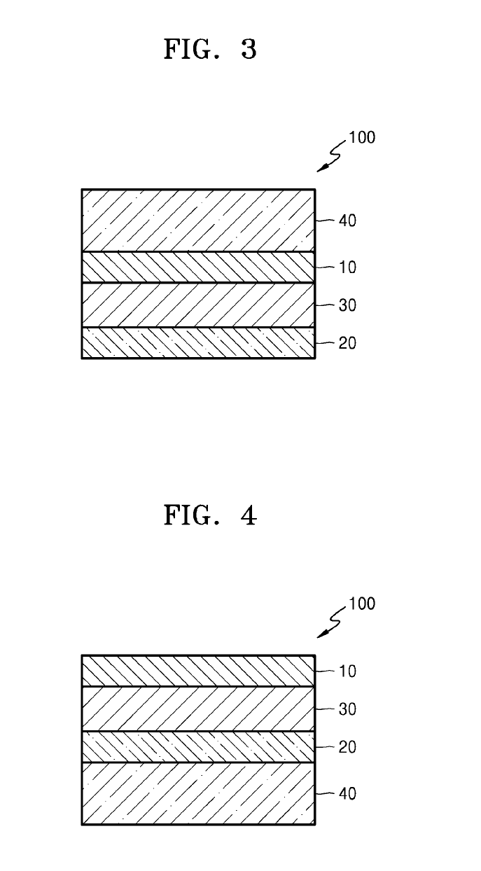

FIG. 3 illustrates a vertical cross-sectional view illustrating a photoreactive smart window according to an exemplary embodiment.

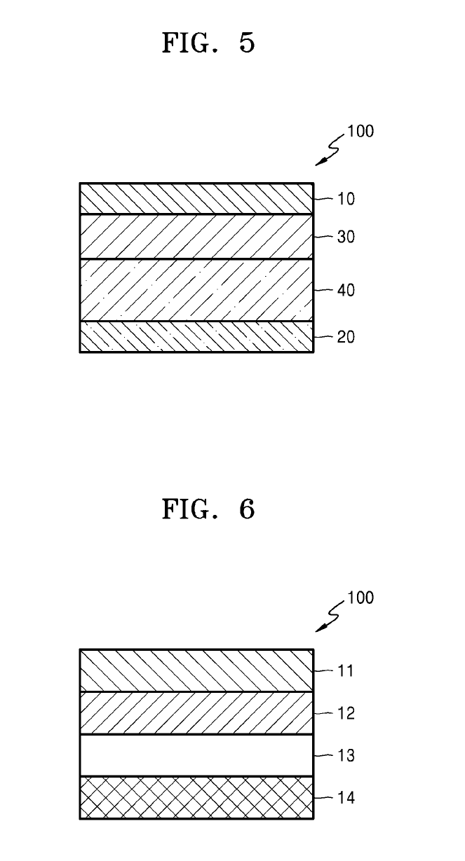

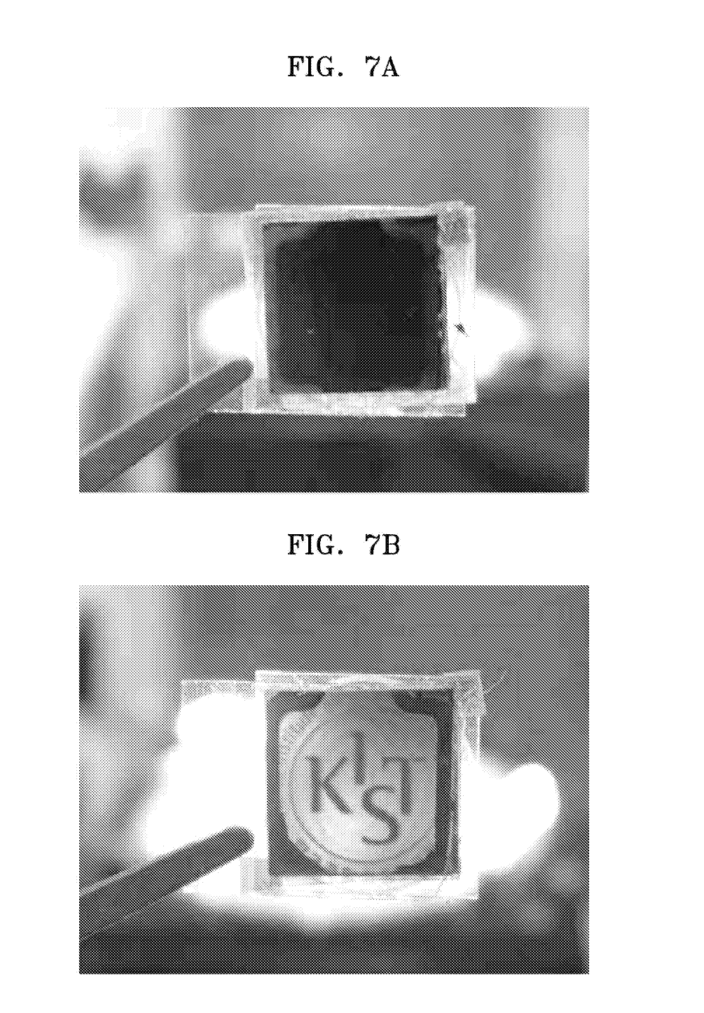

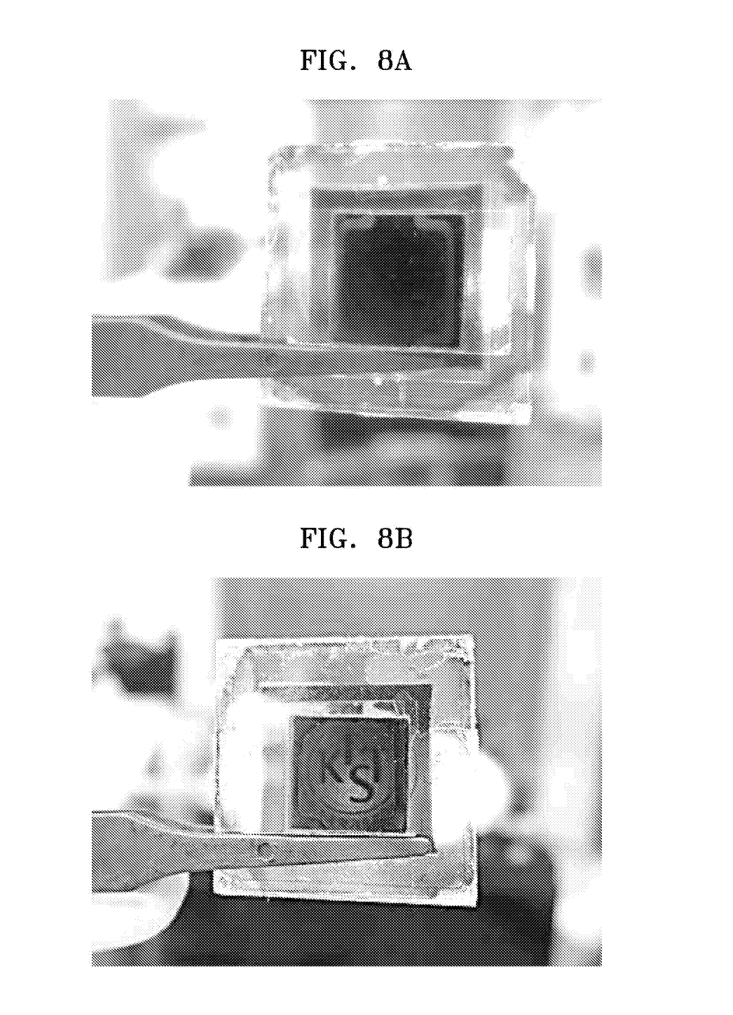

Referring to FIGS. 3 to 5, a photoreactive smart window 100 has a stacked structure including an upper polarizer 10, a lower polarizer 20, a liquid crystal layer 30, and a solar cell 40. The solar cell 40 may be disposed on a top surface of the upper polarizer 10 as shown in FIG. 3, on a bottom surface of the lower polarizer 20 as shown in FIG. 4, between the upper polarizer 10 and the liquid crystal layer 30 as shown in FIG. 5, or between the lower polarizer 20 and the liquid crystal layer 30 as shown in FIG. 6. In such a stacked structure of the photoreactive smart window 100, the solar cell 40 may be integrated with the liquid crystal layer 30 as one body.

Each of the stacked structures of FIGS. 3 to 5 has unique advantages. For example, the structure of FIG. 3 in which the solar cell 40 is disposed on top of the liquid crystal layer 30 may completely collect light incident thereto by the solar cell 40 without loss of incident light passing through the liquid crystal layer 30, expecting relatively high power output.

The structure of FIG. 4 in which the liquid crystal layer 30 is disposed on top of the solar cell 40 may have low light transmittance due to loss of incident light passing through the liquid crystal layer 30. However, the structure of FIG. 4 blocks UV incident to the solar cell 40, thereby solving problems with life degradation caused by UV irradiation.

The structure of FIG. 5 in which the liquid crystal layer 30 and the solar cell 40 are sandwiched between the polarizers 10 and 20 that intersect each other includes the lower polarizer 20 at the bottom of the solar cell 40, thereby preventing the decrease of the intensity of incident light caused by self-absorption of the polarizers.

The solar cell 40 may include, for example, a dye-sensitized solar cell, an organic solar cell, an inorganic thin film solar cell, or a compound conductive solar cell. To utilize the solar cell 40 as a window without the need of curtains, the solar cell 40 needs to be a transparent solar cell to allow transmission of external light. In this regard, a dye-sensitized solar cell formed of organic materials or an organic solar cell may be more preferred to the solar cell 40.

In an exemplary embodiment, the solar cell 40 may be a dye-sensitized solar cell.

A structure of the dye-sensitized solar cell 40 is not particularly limited as long as the structure is generally used in the art.

For example, FIG. 6 illustrates a structure of the dye-sensitized solar cell according to an exemplary embodiment. As such, the solar cell includes a first electrode 11, a light absorbing layer 12, an electrolyte 13, and a second electrode 14, wherein the light absorbing layer 12 includes semiconductor fine particles and dye molecules. The first electrode 11 and the light absorbing layer 12 are considered together as a one semiconductor electrode.

A transparent substrate may be used as the first electrode 11. Such a transparent substrate is not particularly limited as long as a substrate has transparency, such as a glass substrate. Any material having conductivity and transparency may be used as a material used to provide the transparent substrate for conductivity, and for example, a tin-based oxide (e.g., SnO₂), which is conductive and transparent and particularly has excellent thermal stability, and an indium tin oxide (ITO), which is a relatively low-cost material, may be used.

The thickness of the light absorbing layer 12 including a semiconductor particle and a dye may be 15 μm or less, and for example, may be in a range of about 1 μm to about 15 μm, since the light absorbing layer 12 has high series resistance due to its structure and the increased series resistance causes reduction in conversion efficiency. Thus, the thickness of the light absorbing layer 12 is controlled to be 15 μm or less to maintain its function and to maintain the series resistance at a low level and prevent reduction in conversion efficiency.

The semiconductor particle included in the light absorbing layer 12 may include a single elemental semiconductor, e.g. silicon, a compound semiconductor and a perovskite compound. The semiconductor used herein may be an n-type semiconductor which provides an anode current as a result of electrons ejected as carriers due to light excitation. Particularly, the semiconductor particle used herein may be titanium dioxide (TiO₂), SnO₂, ZnO, WO₃, Nb₂O₅, TiSrO₃, or the like, and for example, may be anatase-type TiO₂. Furthermore, the semiconductor particle used herein is not limited thereto, and such a semiconductor particle may be used alone or in combination of at least. As such, the semiconductor particle may have a large surface area for the dye absorbed on the surface of the semiconductor particle to absorb a large amount of light. In this case, the semiconductor particle may have a particle diameter of 20 nm or less.

Any dye that is commonly used in solar cells may be used without limitation as the dye included in the light absorbing layer 12, and for example, a ruthenium (Ru) complex may be used. However, any dye that has a charge separation capability and sensitization may be used without limitation as the dye included in the light absorbing layer 12. In addition to the Ru complex, examples of the dye included in the light absorbing layer 12 are a xanthine-based dye such as a basic dye, such as rhodamine B, rose bengal, eosin, and erythrosine; a cyanine-based dye such as quinocyanine and kryptocyanine; a basic dye such as phenosafranine, tyocyn, and methylene blue; a porphyrin-based compound such as chlorophyll, zinc porphyrin, and magnesium porphyrin; an azo dye; a complex compound such as a phthalocyanine compound and ruthenium trisbipyridyl; an anthraquinone-based dye; and a polycyclic quinone-based dye. The aforementioned dyes may be used alone or in a combination with the ruthenium complex, so as to improve absorption of visible light with a long wavelength and to further enhance light-conversion efficiency. Examples of the ruthenium complex are RuL₂(SCN)₂, RuL₂(H₂O)₂, RuL₃, RuL₂, or the like (wherein L denotes 2,2′-bipyridyl-4,4′-dicarboxylate).

To adsorb the dyes onto the light absorbing layer 12, for example, a solution in which the dye is dispersed is prepared and used to allow precipitation of the light absorbing layer 12. Here, the concentration of the dye in the solution is not specifically limited, so long as the dyes are adsorbed onto the light absorbing layer 12. A solvent used herein may include ethanol, iopropanol, acetonitrile, valeronitrile, or the like, but is not limited thereto. Any material available in the art may be used as the solvent.

A method of manufacturing a light absorbing layer 12 is as follows. A surface of a fine particle of a semiconductor is sprayed, coated, or immersed in a solution in which the organic metal complex of Formula 1 above is dispersed, and then, cleaned and dried, thereby manufacturing a light absorbing layer 12. The light absorbing layer 12 may be manufactured after the fine particle of the semiconductor is formed on the first electrode in advance. A solvent used to disperse an organic metal complex is not particularly limited, and examples thereof are acetonitrile, dichloromethane, alcohol-based solvents, or the like.

The electrolyte 13 is formed of a liquid electrolyte, and may be formed to include the light absorbing layer 12 or to allow permeation of the liquid electrolyte in the light absorbing layer 12. The electrolyte 13 may be, for example, an acetonitrile solution of iodine, but is not limited thereto. Any source capable of conducting holes may be used.

Any conductive agent available in the art may be used for the second electrode 14. In addition, an insulating material may be used, if a conductive layer is disposed on a side facing a semiconductor electrode. Nevertheless, a material that is electrochemically stable may be used as an electrode, and detailed examples thereof are platinum, gold, and carbon. In addition, in consideration of improving the catalytic effects on a redox reaction, the side facing the semiconductor electrode may have a microstructure with an increasing surface area. For example, a platinum material may be prepared as platinum black, and a carbon material may be prepared as a porous material. Such platinum black may be prepared according to an anodic oxidation method using platinum or a treatment using chloroplatinic acid, and such a porous carbon material may be prepared by sintering carbon particles or sintering organic polymers.

A method of manufacturing a dye-sensitized solar cell is widely known in the art and is obvious to those of skill in the art, and thus a detailed description thereof will be omitted.

Hereinafter, one or more embodiments will be described in more detail with reference to the following examples. However, these examples are for illustrative purposes only and are not intended to limit the scope of the one or more embodiments.

### EXAMPLE 1

7 wt % of an azobenzene compound in which the compound of Formula 1 and the compound of Formula 2 were mixed in a molar ratio of 10:1 were mixed with 7 wt % of a chiral dopant, R₂₀₁₁(Merck KGaA), and then, the mixture was dispersed in a nematic host, E7 (Merck KGaA). The resultant chiral-nematic-LC mixture was filled in a cell having a thickness of 5 μm, and then, was inserted between polarizers that intersected each other at a right angle. The cell was coated with a polyimide alignment layer that had abrasion in a reverse direction parallel to an inner surface of a glass substrate.

A dye-sensitized solar cell (DSSC) was prepared as follows.

A fluorine-doped tin oxide (FTO) transparent conductor was coated to an area of 0.18 cm² with a dispersion solution of titanium oxide particles having a particle diameter in a range of about 15 nm to about 20 nm. Then, according to a sintering process performed at a temperature of 500° C. for 30 minutes, a porous titanium oxide thick film having a thickness of 15 μm was prepared. Then, the porous titanium oxide thick film was subjected to an adsorption treatment for at least 18 hours using a 0.2 mM N719 dye solution dissolved in ethanol. Afterwards, the dye-adsorbed porous titanium oxide thick film was washed with ethanol, and then, dried to prepare a semiconductor electrode.

To prepare a counter electrode, a platinum (Pt) layer was deposited on the FTO transparent conductor by using a sputter. The counter electrode had small holes made by using a drill (0.6 mm) to facilitate injection of an electrolyte solution.

Then, a thermoplastic polymer film having a thickness of 60 μm was placed between the semiconductor electrode and the counter electrode, and then, pressed at a temperature of 90° C. for 10 seconds. Thus, the two electrodes were bonded to each other. The metal electrode used herein had a thin thickness (5 nm) to increase light transmittance. An oxidation-reduction electrolyte was injected through the small holes in the counter electrode, and then, the small holes were sealed by a cover glass and a thermoplastic polymer film, thereby completing the manufacture of a DSSC. The oxidation-reduction electrolyte used herein was a solution in which 0.62M 1-methyl-3-propylimidazolium iodide, 0.1 M LiI, 0.5M I₂, and 0.5M 4-tert-butylpyridine were dissolved in acetonitrile.

The DSSC prepared as described above was placed below the liquid crystal layer to be integrated as shown in FIG. 4, thereby manufacturing a photoreactive smart window.

The characteristics and performance of the fabricated device were measured as follows.

A SAN-El ELECTRIC solar simulator equipped with a 300 W Xe lamp as a light source and an AM 1.5 G filter was used to measure the AM 1.5 G solar spectrum. An irradiation intensity of 100 mW/cm⁻² was adjusted to that of a standard silicon solar cell, and the current density was measured by using a Keithely 2400 device. The light transmittance was measured by using a VARIAN 5000 UV-Vis spectrophotometer.

### EVALUATION EXAMPLE 1

### Experiment for the Switching Performance of a Liquid Crystal Layer According to UV Exposure

The liquid crystal layer prepared according to Example 1 and inserted between the polarizers that intersect each other was exposed to a solar stimulator (AM1.5 G, 100 mW cm⁻² 1 sun condition) for 60 seconds in the absence of the DSSC. FIGS. 7A and 7B show images of the liquid crystal layer in a state before exposure to UV light and in a state after exposure to UV light, respectively.

Referring to FIG. 7, FIG. 7A shows that the liquid crystal layer is in a dark condition before being exposed to UV light, and FIG. 7B shows that the liquid crystal layer is in a transparent condition after being exposed to UV light. The conversion into the transparent condition upon the exposure to UV light was not made using room light having a relatively low UV intensity.

The smart window prepared according to Example 1, i.e., the smart window including the liquid crystal layer that was combined with the DSSC, was exposed to UV light under the same conditions. FIGS. 8A and 8B show images of the smart window in a state before exposure to UV light and in a state after the exposure to UV light, respectively.

Referring to FIG. 8, FIG. 8A shows that the smart window is in a dark condition before being exposed to UV light, and FIG. 8B shows that the smart window is in a transparent condition after being exposed to UV light. That is, the images indicate that the smart window may be in a dark condition or in a transparent condition according to the mode-switching performance of the liquid crystal layer.

### EVALUATION EXAMPLE 2

### Evaluation of the Light Transmittance of the Liquid Crystal Layer

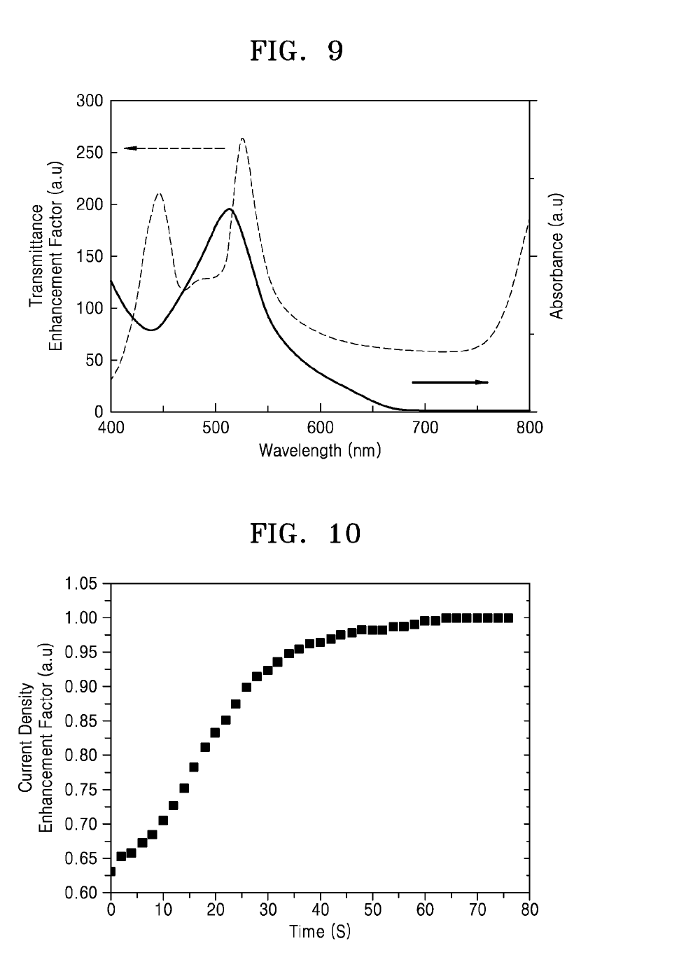

The light transmittance of the liquid crystal layer prepared according to Example 1 and inserted between the polarizers that intersect each other was measured by using an UV-Vis spectrometer, and the results are shown in FIG. 9.

Referring to FIG. 9, it was confirmed that the liquid crystal layer improved the light transmittance in the DSSC at a wavelength of about 550 nm at which a dye or a trimer ruthenium complex absorbs light.

### EVALUATION EXAMPLE 3

### Performance Evaluation of the Smart Window

To confirm the switching performance of the smart window of Example 2 in the ‘night mode’ and the ‘day mode’, the smart window was evaluated as follows.

First, to confirm whether the smart window remained in the night mode in the absence of UV light, a 395 nm cut-off long pass filter was used to intercept UV generated by a solar simulator. The liquid crystal layer was in a dark condition, and the smart window exhibited a dark photodiode-like behavior.

Then, to confirm whether the smart window switched from the ‘night mode’ to the ‘day mode’, the 395 nm cut-off long pass filter was removed from the solar simulator, and then, the photocurrent through the smart window was measured at a 2-second interval. The evaluation results regarding the current-density of the smart window as a time function are shown in FIG. 10.

As shown in FIG. 10, the current density of the smart window increased with a longer exposure time to UV light. In addition, it was confirmed that the smart window quickly switched from the night mode to the day mode since the photocurrent through the smart window saturated in 60 seconds.

As described above, according to the one or more of the above exemplary embodiments, a photoreactive smart window may adjust the light transmittance according to the presence of UV light without requiring external energy and may be combined with a solar cell to generate electricity. The photoreactive smart window is in a transparent state in the daytime when UV light is generated so that sunlight passing through the window may be converted into electric energy. Alternatively, the photoreactive smart window is in an opaque state in the evening and at night when no UV light is generated, and thus can be used as a window without the need of curtains.

It should be understood that the exemplary embodiments described therein should be considered in a descriptive sense only and not for purposes of limitation. Descriptions of the features or aspects within each embodiment should typically be considered as being available for other similar features or aspects in other embodiments.

While one or more exemplary embodiments have been described with reference to the figures, it will be understood by those of ordinary skill in the art that various changes in form and details may be made therein without departing from the spirit and scope of the inventive concept as defined by the following claims.

What is claimed is:

1. A photoreactive smart window comprising:
an upper polarizer and a lower polarizer that are arranged at a separation distance from each other;
a liquid crystal layer between the upper polarizer and the lower polarizer and comprising an achiral nematic liquid crystal, a photoreactive azobenzene compound, and a chiral dopant; and
a solar cell disposed on a top surface of the upper polarizer, on a bottom surface of the lower polarizer, between the upper polarizer and the liquid crystal layer, or between the lower polarizer and the liquid crystal layer.

2. The photoreactive smart window of claim 1, wherein the upper polarizer and the lower polarizer intersect at a right angle.

3. The photoreactive smart window of claim 1, wherein the achiral nematic liquid has a helical structure having a helical axis in a thickness direction of the liquid crystal layer, and
wherein a pitch of the helical structure is adjusted via the azobenzene compound according to the presence or absence of UV light.

4. The photoreactive smart window of claim 3, wherein the pitch of the helical structure of the achiral nematic liquid decreases with the absence of UV light and increases with the presence of UV light.

5. The photoreactive smart window of claim 1, wherein the azobenzene compound is configured as a trans-isomer in the absence of UV light and as a cis-isomer in the presence of UV light.

6. The photoreactive smart window of claim 1, wherein the azobenzene compound comprises a compound represented by Formula 1 below: 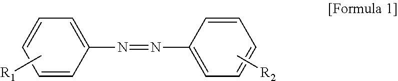
wherein R₁ and R₂ are each independently a hydrogen, a substituted or unsubstituted C₁-C₃₀ alkyl group, a substituted or unsubstituted C₁-C₃₀ alkoxy group, a substituted or unsubstituted C₆-C₃₀ aryl group, a substituted or unsubstituted C₆-C₃₀ aryloxy group, a substituted or unsubstituted C₃-C₃₀ heteroaryl group, a substituted or unsubstituted C₃-C₃₀ heteroaryloxy group, a substituted or unsubstituted C₄-C₃₀ cycloalkyl group, or a substituted or unsubstituted C₃-C₃₀ heterocycloalkyl group, and
wherein the aryl group, the aryloxy group, the heteroaryl group, and the heteroaryloxy group are hybridized to at least two carbon atoms of a combined benzene ring.

7. The photoreactive smart window of claim 1, wherein the azobenzene compound comprises a compound represented by Formula 2 below: 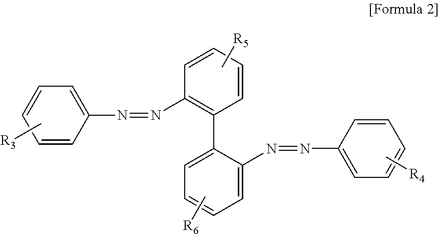
wherein R₃ to R₆ are each independently a hydrogen, a substituted or unsubstituted C₁-C₃₀ alkyl group, a substituted or unsubstituted C₁-C₃₀ alkoxy group, a substituted or unsubstituted C₆-C₃₀ aryl group, a substituted or unsubstituted C₆-C₃₀ aryloxy group, a substituted or unsubstituted C₃-C₃₀ heteroaryl group, a substituted or unsubstituted C₃-C₃₀ heteroaryloxy group, a substituted or unsubstituted C₄-C₃₀ cycloalkyl group, or a substituted or unsubstituted C₃-C₃₀ heterocycloalkyl group, and
wherein the aryl group, the aryloxy group, the heteroaryl group, and the heteroaryloxy group are hybridized to at least two carbon atoms of a combined benzene ring.

8. The photoreactive smart window of claim 6, wherein the azobenzene compound comprises a compound represented by Formula 3 below or a mixture of the compound of Formula 3 and a compound represented by Formula 4 below:

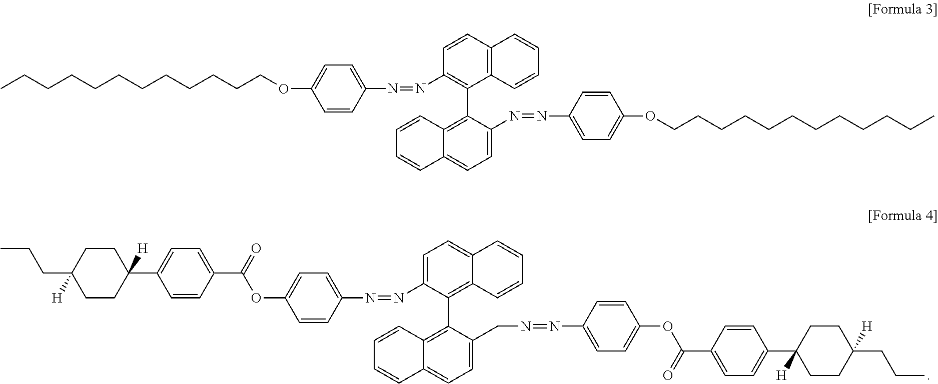

9. The photoreactive smart window of claim 8, wherein the compound of Formula 3 and the compound of Formula 4 are mixed in a molar ratio in a range of about 1:100 to about 100:1.

10. The photoreactive smart window of claim 1, wherein the photoreactive smart window is opaque in the absence of UV light and is transparent in the presence of UV light.

11. The photoreactive smart window of claim 1, wherein the solar cell is transparent.

12. The photoreactive smart window of claim 1, wherein the solar cell is a dye-sensitized solar cell, an organic solar cell, an inorganic thin film solar cell, or a compound semiconductor solar cell.

13. The photoreactive smart window of claim 1, wherein the solar cell is a dye-sensitized solar cell.
